(19) United States
(12) Patent Application Publication
(10) Pub. No.: US 2017/0271294 A1
(43) Pub. Date: Sep. 21, 2017

(54) SPACER PARTICLES FOR BOND LINE THICKNESS CONTROL IN SINTERING PASTES

(71) Applicant: Indium Corporation, Clinton, NY (US)

(72) Inventors: Sihai Chen, New Hartford, NY (US); Ning-Cheng Lee, New Hartford, NY (US)

(73) Assignee: Indium Corporation, Clinton, NY (US)

(21) Appl. No.: 15/460,023

(22) Filed: Mar. 15, 2017

Related U.S. Application Data
(60) Provisional application No. 62/308,761, filed on Mar. 15, 2016.

(51) Int. Cl. H01L 23/00; H01L 21/48

(52) U.S. Cl. CPC H01L 24/29; H01L 24/83; H01L 21/4867; H01L 2224/29239; H01L 2224/26125; H01L 2224/29311; H01L 2224/29316; H01L 2224/29387; H01L 2924/0503; H01L 2924/05442; H01L 2924/05432; H01L 2224/29309; H01L 2224/29363; H01L 2224/29313; H01L 2924/01032; H01L 2224/8384

(57) ABSTRACT

Methods and compositions are described for controlling bond line thickness of a joint formed during sintering. Spacer particles of a predetermined particle type and size are added in a predetermined concentration to a sintering paste to form a sintering paste mixture prior to sintering to achieve a targeted bond line thickness during sintering. The sintering paste mixture can be sintered under pressure and pressure-less process conditions. Under pressured sintering, the amount of pressure applied during sintering may be adjusted depending on the composition and concentration of the spacer particles to adjust bond line thickness.

### CROSS-REFERENCE TO RELATED APPLICATIONS

This application document claims the benefit of U.S. Provisional Patent Application No. 62/308,761, filed on Mar. 15, 2016.

### TECHNICAL FIELD

The present disclosure relates generally to a sintering die-attach technique for electronic devices and, in particular, to bond line thickness control of joints formed by sintering.

### DESCRIPTION OF THE RELATED ART

Die attachment is a well-known process of bonding a die containing an integrated circuit to a substrate, package, or another die in the formation of electronic devices. High temperature electronics require die attaches that have a high melting point. Conventionally, high-lead, high melting temperature solders were used for bonding high temperature electronic devices. However, due to increasing requirements for higher service and operating temperatures, and higher thermal and electrical conductivity, suitable for next generation high power devices such as insulated-gate bipolor transistors (IGBT), high-lead solder materials are reaching a performance limitation. Moreover, due to increasing environmental concerns and regulation over the use of high-lead solder material in the electronics fields, alternatives to high-lead solder materials have been sought.

More recently, the sintering of silver (Ag) pastes to form highly reliable joints has been used in die-attach applications requiring high temperatures. Presently, sintering under high pressure is used to form Ag-joints. In the conventional Ag-paste sintering process, the Ag-paste is dispensed on a direct bond copper (DBC) substrate, subsequently dried, and a die is placed on top of the dried paste. This is followed by the application of high pressure (up to 50 MPa) and a heating temperature (e.g., 250° C.) for the sintering to occur.

The application of high pressure (tens of MPa) during sintering requires expensive, specialized tooling that inevitably lowers throughput. Some Ag-pastes incorporate polymeric ingredients that avoid the need for high pressure sintering. However, the reduction in pressure through the use of polymeric ingredients comes at the cost of higher Ag-porosity and lower joint bond strength, which results in a joint having poor reliability, and poor electrical and thermal conductivity.

### BRIEF SUMMARY OF EMBODIMENTS

Embodiments described herein are directed to using spacer particles in a sintering paste to control bond line thickness of a joint formed during sintering.

In one embodiment, a sintering paste mixture includes: a plurality of silver particles; a solvent; and a plurality of spacer particles, where the plurality of spacer particles have a particle diameter within a target bond line thickness range of a joint formed by sintering an assembly using the sintering paste mixture. In one implementation, the sintering paste mixture may be formed by mixing the plurality of spacer particles with an already formed sintering paste including the silver particles and solvent. In another implementation, the sintering paste mixture may be formed during formation of the sintering paste.

In another embodiment, a method of sintering includes: forming a sintering paste mixture by mixing a plurality of spacer particles, a plurality of silver particles, and solvent, where the plurality of spacer particles have an average particle diameter within a target bond line thickness range of a joint formed by sintering an assembly using the sintering paste mixture; dispensing the sintering paste mixture on a substrate; placing a device on the sintering paste mixture to form an assembly; and sintering the assembly to form a sintered joint, wherein the sintered joint has a bond line thickness within the target bond line thickness range. The device may be a die including a circuit board.

In another embodiment, a joint with a targeted bond line thickness range is formed in a die-attach sintering process by using an Ag paste mixture including a spacer particle having a size within the targeted bond line thickness range. In various implementations of this embodiment, the targeted bond line thickness range is 30 μm to 300 μm. In preferred embodiments, the bond line thickness is from 50 μm to 150 μm, and more particularly, from 60 μm to 100 μm.

In further embodiments, the spacer particles comprise a composition metal particle, a solder ball such as Sn—Pb or no lead solder, or an inorganic particle. In implementations, the composition metal particle is gold, silver, or copper. In implementations, the inorganic particles are boron nitride (BN), silica (SiO2) or aluminium oxide (Al2O3).

In further embodiments, the spacer particles include at least one of indium (In), germanium (Ga), bismuth (Bi), or tin (Sn). In particular implementations, the spacer particles comprise greater than 50 mass % of one of In, Ga, Bi, or Sn.

In another embodiment, an Ag paste for a die-attach sintering application is formed by determining a targeted bond line thickness range for a joint; and combining Ag particles with spacer particles having a size within the targeted bond line thickness range. In implementations of this embodiment, the Ag paste comprises between greater than 0 wt % and less than 4 wt % spacer particles.

In an embodiment, a die-attach joint is formed by the process of: dispensing a sintering paste on a substrate; placing a die on the paste to form an assembly; and sintering the assembly to form the joint; wherein the paste comprises between greater than 0 wt % and less than 4 wt % spacer particles; and wherein the bond line thickness of the joint is 30 μm to 300 μm. In implementations of this embodiment, the assembly is sintered at a pressure between 5 and 35 psi. In embodiments, the sintering pressure is increased to decrease the bond line thickness of the joint.

In implementations, the amount of pressure applied during sintering is based at least in part on the wt % of the plurality of spacer particles.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The technology disclosed herein, in accordance with one or more various embodiments, is described in detail with reference to the included figures. The drawings are provided for purposes of illustration only and merely depict typical or example embodiments of the disclosed technology. These drawings are provided to facilitate the reader's understanding of the disclosed technology and shall not be considered limiting of the breadth, scope, or applicability thereof.

FIG. 1 is an operational flow diagram illustrating an example sintering process that may be implemented using a sintering mixture in accordance with embodiments disclosed herein.

FIG. 2 illustrates an example electronic device or electronic component such as a semiconductor component after various operations of the process of FIG. 1.

FIG. 3 is a plot illustrating the relationship between spacer concentration and bond line thickness under different pick and place probe pressures.

FIG. 4 is a plot illustrating the relationship between pick and place probe pressure and bond line thickness under different spacer concentrations.

The figures are not intended to be exhaustive or to limit the invention to the precise form disclosed. It should be understood that the invention can be practiced with modification and alteration, and that the disclosed technology be limited only by the claims and the equivalents thereof.

### DETAILED DESCRIPTION OF THE EMBODIMENTS

In accordance with various embodiments, methods and compositions are disclosed for controlling bond line thickness of a joint formed during sintering (e.g., sintering for die-attach applications.) In embodiments, spacer particles of a predetermined particle type and size are added in a predetermined concentration to a sintering paste prior to sintering to achieve a targeted bond line thickness during sintering. The paste can be sintered under pressure and pressure-less process conditions. In some embodiments, the pressure of a pick and place probe used during sintering of the paste with spacer particles may be increased to decrease the bond line thickness.

Although embodiments described herein will be described primarily with reference to adding spacer particles to an Ag-sintering paste, it should be noted that in other embodiments spacer particles may be used in other sintering pastes, such as, for example, a Cu sintering paste.

Before describing, in detail, embodiments of the disclosed methods and compositions for controlling bond line thickness of a joint during sintering applications, it is instructive to describe the benefits of controlling bond line thickness.

As described in U.S. patent application Ser. No. 15/142,263, titled “Nanomicrocrystallite Paste for Pressureless Sintering,” which is incorporated herein by reference in its entirety, a novel Ag-paste without any polymeric ingredients for pressure-less sintering die attach processes was recently developed. The sintered joints exhibit high joint shear strength, and a high tolerance toward high temperature aging treatment, thus enabling the advancement of high power devices at a low conversion cost.

During the study of a 250° C. thermal aging test with silver sintering joints obtained with pressure-less sintering profiles as described above, it was found that bond line thickness played a critical role in the reliability of the joints as measured by shear strength. It was found that after thermal aging, within the Ag sintering layer, Ag migrates toward the direct bond copper (DBC) substrate to form a dense layer of AgCuNi(Au), thus increasing the porosity of the Ag sintering joint due to the loss of Ag. Without being bound to a particular theory, the Ag migration could be attributed to the tendency of Ag to form an alloy with Au, Ni, and Cu at the DBC side, and may be also affected by the chemistry of the nano-Ag paste.

For a thin bond line thickness (e.g., less than 20 um), void and cracks generated easily after aging, due to the silver diffusion to the interfaces between silver and substrates. One important finding is that with a higher bond line thickness, the porosity increase of the Ag sintering joint is greatly retarded, thus resulting in the formation of a joint with higher reliability.

Accordingly, bond line thickness is an important parameter in a sintering joint used for high temperature and high power die-attach applications. To obtain a high-reliability joint during a sintering process, it is important to keep the bond line thickness within a proper range (e.g., above a certain thickness). In order to prevent possible device failure for high reliability applications, methods to control the bond line thickness become important. As further described below, spacer particles may be used to control bond line thickness.

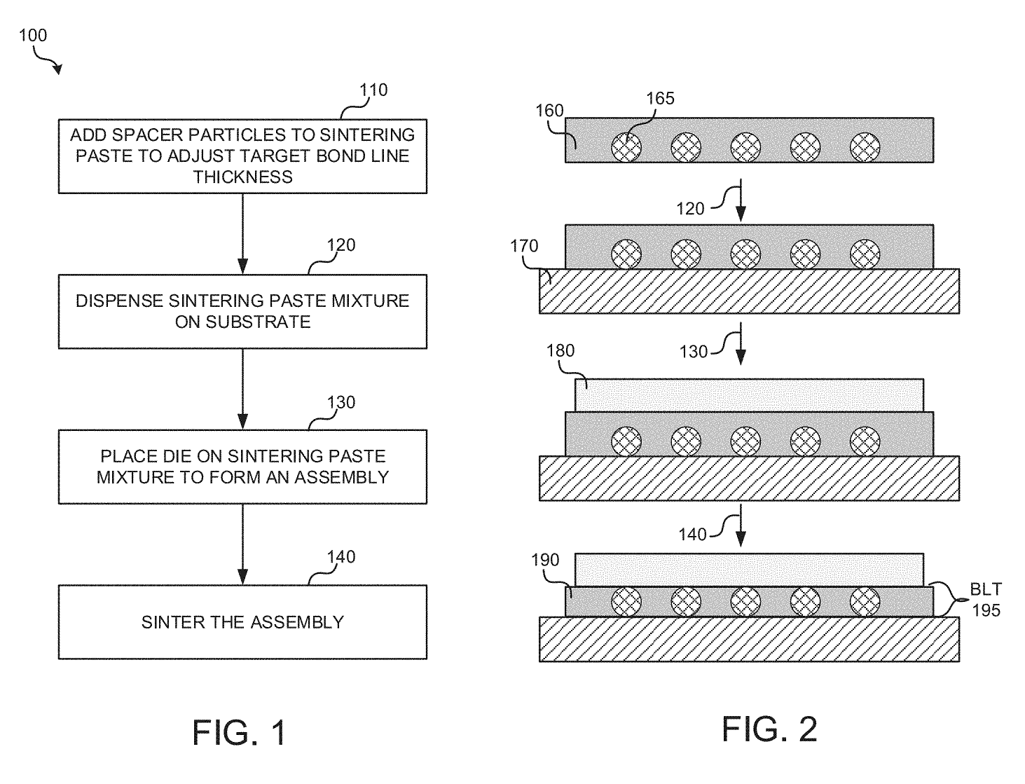

FIG. 1 is an operational flow diagram illustrating an example sintering process 100 that may be implemented using a sintering mixture with spacer particles in accordance with embodiments disclosed herein. FIG. 1 will be described concurrently with FIG. 2, which illustrates an example electronic device or electronic component such as a semiconductor component after various operations of the process of FIG. 1.

At operation 110, spacer particles 165 are added to a sintering paste 160 to form a sintering paste mixture to adjust a target bond line thickness of an electronic assembly formed by the sintering process. The sintering paste mixture may be created during preparation of the sintering paste by mixing Ag particles, a solvent, and the spacer particles during preparation of the sintering paste. Alternatively, the sintering paste mixture may be created by adding the spacer particles to a preexisting sintering paste already comprising Ag particles and solvent.

In embodiments, the spacer particles may be combined with Ag particles and a solvent (e.g., an Ag sintering paste) such that they make up between greater than 0 wt % and less than 4 wt % of the combination. In embodiments, the Ag particles may have an average particle size or diameter from 10 nm to 100 um. In embodiments, the Ag particles may make up between 50 wt % and 95 wt % of the sintering paste mixture. The solvent may be a polyglycol solvent or other suitable sintering solvent.

In various embodiments, a targeted bond line thickness range is achieved by adding spacer particles having an average particle size or diameter within the targeted bond line thickness range. In embodiments, the targeted bond line thickness of a silver joint may be between 30 μm and 500 μm. In preferred embodiments, the bond line thickness is from 50 μm to 300 μm, and more particularly, from 60 μm to 100 μm.

In some implementations, the spacer particles are single composition metal particles such as gold, silver, or copper. In alternative implementations, the spacer particles are provided by way of a solder ball. In these implementations, the solder ball may be a Sn—Pb or no lead solder ball such as, for example Sn—Ag—Cu solder balls such as SAC 105, SAC 205, SAC 305, SAC 387, and the like. In further implementations, the spacer particles are inorganic particles such as boron nitride (BN), silica (SiO2), aluminium oxide (Al2O3), and the like.

In yet further implementations, the spacer particles can be low melting point metal alloys, with a liquidus temperature from 25° C. to about 250° C. Table 1, below, includes a non-exhaustive list of example low melting point alloys that may be used as spacer particles.

TABLE 1
Low melting point alloys that may be used as spacer particles

| Liquidus | | | | | | | | | |
|---|---|---|---|---|---|---|---|---|---|
| (° C.) | Solidus (° C.) | Elemental Composition (% by Mass) | | | | | | | |
| 25 | 16 | 95.0 | Ga | 5.0 | In | | | | |
| 30 | | 100.0 | Ga | | | | | | |
| 60 | 60 | 51.0 | In | 32.5 | Bi | 16.5 | Sn | | |
| 72 | 72 | 66.3 | In | 33.7 | Bi | | | | |
| 79 | 79 | 57.0 | Bi | 26.0 | In | 17.0 | Sn | | |
| 81 | 81 | 54.0 | Bi | 29.7 | In | 16.3 | Sn | | |
| 108 | 108 | 52.2 | In | 46.0 | Sn | 1.8 | Zn | | |
| 109 | 109 | 67.0 | Bi | 33.0 | In | | | | |
| 112 | 98 | 51.6 | Bi | 41.4 | Pb | 7.0 | Sn | | |
| 118 | 118 | 52.0 | In | 48.0 | Sn | | | | |
| 125 | 118 | 50.0 | In | 50.0 | Sn | | | | |
| 131 | 118 | 52.0 | Sn | 48.0 | In | | | | |
| 138 | 138 | 58.0 | Bi | 42.0 | Sn | | | | |
| 140 | 139 | 57.0 | Bi | 42.0 | Sn | 1.0 | Ag | | |
| 143 | 96 | 33.4 | Bi | 33.3 | Pb | 33.3 | Sn | | |
| 143 | 143 | 97.0 | In | 3.0 | Ag | | | | |
| 145 | 118 | 58.0 | Sn | 42.0 | In | | | | |
| 150 | 125 | 95.0 | In | 5.0 | Bi | | | | |
| 150 | | 99.3 | In | 0.7 | Ga | | | | |
| 151 | 143 | 90.0 | In | 10.0 | Sn | | | | |
| 152 | | 99.4 | In | 0.6 | Ga | | | | |
| 153 | | 99.6 | In | 0.4 | Ga | | | | |
| 154 | | 99.5 | In | 0.5 | Ga | | | | |
| 157 | | 100.0 | In | | | | | | |
| 170 | 138 | 60.0 | Sn | 40.0 | Bi | | | | |
| 186 | 174 | 86.5 | Sn | 5.5 | Zn | 4.5 | In | 3.5 | Bi |
| 187 | 175 | 77.2 | Sn | 20.0 | In | 2.8 | Ag | | |
| 187 | 181 | 83.6 | Sn | 8.8 | In | 7.6 | Zn | | |
| 199 | 199 | 91.0 | Sn | 9.0 | Zn | | | | |
| 205 | 204 | 86.9 | Sn | 10.0 | In | 3.1 | Ag | | |
| 210 | 177 | 55.0 | Pb | 44.0 | Sn | 1.0 | Ag | | |
| 213 | 211 | 91.8 | Sn | 4.8 | Bi | 3.4 | Ag | | |
| 217 | 217 | 90.0 | Sn | 10.0 | Au | | | | |
| 220 | 217 | 95.5 | Sn | 3.8 | Ag | 0.7 | Cu | | |
| 220 | 217 | 95.5 | Sn | 3.9 | Ag | 0.6 | Cu | | |
| 220 | 217 | 96.5 | Sn | 3.0 | Ag | 0.5 | Cu | | |
| 221 | 221 | 96.5 | Sn | 3.5 | Ag | | | | |
| 224 | 221 | 97.0 | Sn | 3.0 | Ag | | | | |
| 225 | 217 | 95.5 | Sn | 4.0 | Ag | 0.5 | Cu | | |
| 225 | 217 | 96.2 | Sn | 2.5 | Ag | 0.8 | Cu | 0.5 | Sb |
| 226 | 217 | 98.5 | Sn | 1.0 | Ag | 0.5 | Cu | | |
| 226 | 221 | 97.5 | Sn | 2.5 | Ag | | | | |
| 227 | 215 | 98.5 | Sn | 1.0 | Ag | 0.5 | Cu | | |
| 227 | 217 | 98.5 | Sn | 0.5 | Ag | 1.0 | Cu | | |
| 227 | 217 | 99.0 | Sn | 0.3 | Ag | 0.7 | Cu | | |
| 227 | 227 | 99.0 | Sn | 1.0 | Cu | | | | |
| 227 | 227 | 99.3 | Sn | 0.7 | Cu | | | | |
| 227 | 227 | 99.2 | Sn | 0.5 | Cu | 0.3 | Bi | | |
| 227 | 227 | 99.5 | Sn | 0.5 | Cu | | | | |
| 232 | | 100.0 | Sn | | | | | | |
| 233 | | 65.0 | Sn | 25.0 | Ag | 10.0 | Sb | | |
| 234 | 232 | 99.0 | Sn | 1.0 | Sb | | | | |
| 237 | 143 | 90.0 | In | 10.0 | Ag | | | | |
| 237 | 235 | 97.0 | Sn | 3.0 | Sb | | | | |
| 240 | 221 | 95.0 | Sn | 5.0 | Ag | | | | |
| 240 | 237 | 95.0 | Sn | 5.0 | Sb | | | | |
| 251 | 134 | 95.0 | Bi | 5.0 | Sn | | | | |

Following preparation of the sintering paste with the spacer particles to form a sintering paste mixture, at operation 120 the sintering paste mixture is placed on a substrate 170. For example, the sintering paste mixture may be placed on a DBC substrate including a ceramic tile and a sheet of copper bonded on one or both sides. In one implementation, the sintering paste mixture is stencil printed on the substrate.

Alternatively, in other embodiments (not illustrated by FIGS. 1-2), the sintering paste mixture may be prepared after stencil printing or otherwise placing a sintering paste on the substrate. In such embodiments, the spacer particles are added to the sintering paste after it has already been printed on the substrate.

At operation 130, a die or wafer 180 containing an integrated circuit is placed on the sintering paste mixture, thereby forming an assembly in preparation for sintering. For example, a Si or GaAs die containing a printed circuit board may be placed on the sintering paste using a pick and place machine. In particular embodiment embodiments, the printed circuit board may correspond to an insulated-gate bipolor transistors (IGBT) chip.

At operation 140, the assembly is sintered, thereby forming a joint 190 between the die and substrate with a bond line thickness 195. During sintering operation 140, the assembly is heated (e.g., using an oven or heating plates) to a sintering temperature and pressure may be applied during sintering. As the assembly heats up and pressure is applied, the sintering paste mixture may sinter. The assembly is heated for a suitable time (e.g., following a predetermined sintering temperature profile) and subsequently cooled down. In implementations, pressure may be applied using a pick and place tool. By controlling the amount of pressure applied by the pick and place tool (in addition to the type and amount of spacer particles 165 mixed into the sintering paste 160 during operation 110), bond line thickness 195 may be controlled.

### EXPERIMENTAL RESULTS

Exemplary implementations, illustrating the bond line thickness control ability of the spacer particles, are described below with reference to an Ag paste including Ag particles with a size of approximately 70 μm. As described below, through the control of the loading concentration of spacer, and also through the control of the pick and place probe pressure, bond line thickness can be controlled.

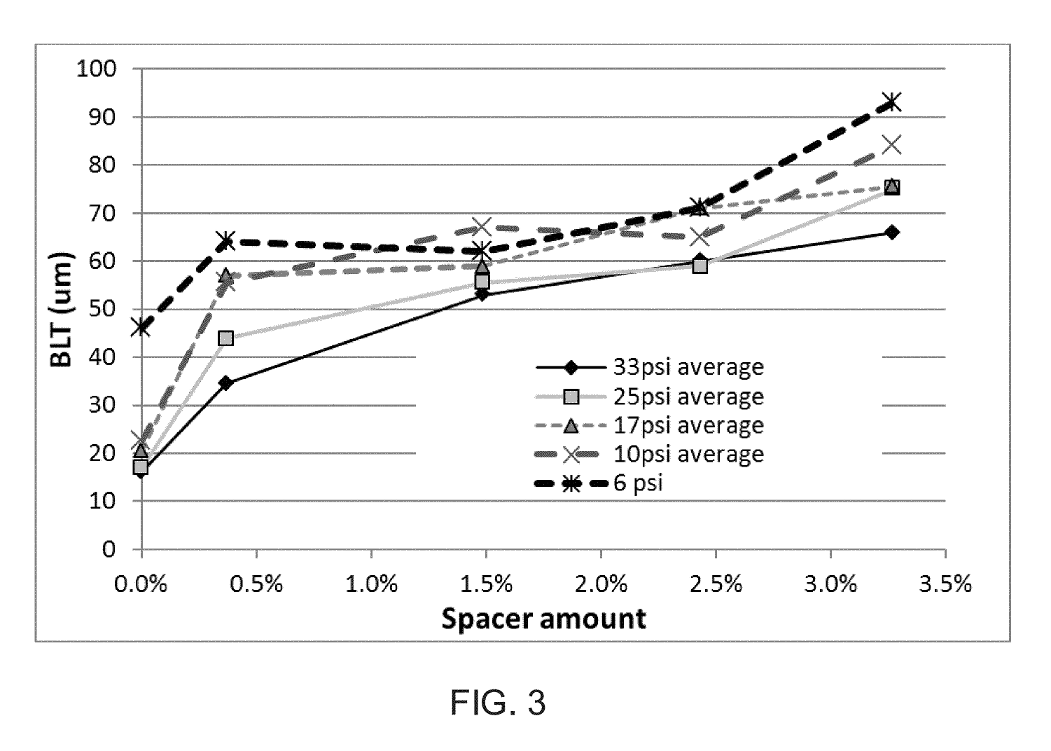

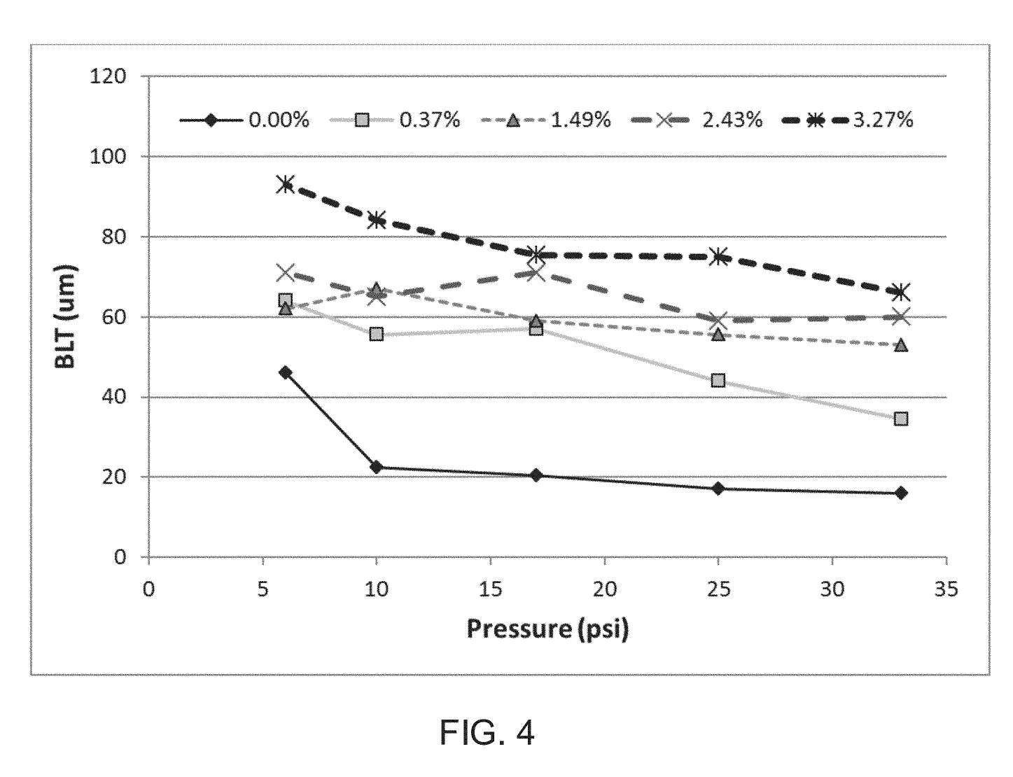

Five samples were tested with an Ag-paste with a spacer particle amount increased from 0 wt % to 3.27 wt %. Additionally, the pressure applied by a pick and place machine was varied. Table 2 in combination with FIGS. 3-4 illustrate the bond line thickness in μm as a function of the spacer particle wt % and pressure applied by the pick and place tool.

TABLE 2
Bond line thickness (μm) of the silver sintering joint under different
spacer concentrations and different pick and place probe pressures

| Spacer | | | | | |
|---|---|---|---|---|---|
| weight | 33 psi | 25 psi | 17 psi | 10 psi | |
| percentage | average | average | average | average | 6 psi |
| 0.00% | 16 | 17 | 20.5 | 22.5 | 46 |
| 0.37% | 34.5 | 44 | 57 | 55.5 | 64 |
| 1.49% | 53 | 55.5 | 59 | 67 | 62 |
| 2.43% | 60 | 59 | 71 | 65 | 71 |
| 3.27% | 66 | 75 | 75.5 | 84 | 93 |

FIG. 3 is a plot illustrating the relationship between spacer concentration and bond line thickness under different pick and place probe pressures. As illustrated by FIG. 3, in embodiments, increasing the spacer particle amount may maintain the bond line thickness within a target range (e.g., 60 μm to 100 μm). For example, at a spacer amount of 3.27 wt %, regardless of the pressure applied by the pick and place tool, the bond line thickness can be controlled within the range of 66 to 93 μm. As illustrated, in embodiments, by loading a proper spacer amount in the Ag paste, bond line thickness may be controlled.

FIG. 4 is a plot illustrating the relationship between pick and place probe pressure and bond line thickness under different spacer concentrations. As illustrated by FIG. 4, at various pick and place probe pressures, the bond line thickness increased as the spacer concentration (wt %) in the Ag paste increased. This illustrates that without spacer particles, it is difficult to control the bond line thickness unless the applied pressure is very low (e.g., 6 psi in this case). Moreover, as the amount of spacer concentration increased, the bond line thickness still remained sensitive to pressure, but shifted to a higher bond line thickness, indicating the importance of the spacer particles.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that can be included in the disclosed technology. The disclosed technology is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the technology disclosed herein. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. A sintering paste mixture, consisting essentially of:
a plurality of silver (Ag) particles;
a solvent; and
a plurality of spacer particles, wherein the plurality of spacer particles have a particle diameter within a target bond line thickness range of a joint formed by sintering an assembly using the sintering paste mixture.

2. The sintering paste mixture of claim 1, wherein the plurality of spacer particles are less than 4 wt % of the sintering paste mixture.

3. The sintering paste mixture of claim 2, wherein the target bond line thickness range is between 30 μm and 300 μm.

4. The sintering paste mixture of claim 3, wherein the target bond line thickness range is between 50 μm to 150 μm

5. The sintering paste mixture of claim 4, wherein the target bond line thickness is between 60 μm and 100 μm.

6. The sintering paste mixture of claim 3, wherein the spacer particles comprise a single composition metal particle, a Sn—Pb or no lead solder ball, or an inorganic particle.

7. The sintering paste mixture of claim 6, wherein the spacer particles comprise an inorganic particle, wherein the inorganic particle comprises boron nitride, silica, or aluminium oxide.

8. The sintering paste mixture of claim 6, wherein the spacer particles comprise single composition metal particles.

9. The sintering paste mixture of claim 3, wherein the spacer particles comprise at least one of indium (In), germanium (Ga), bismuth (Bi), or tin (Sn).

10. The sintering paste mixture of claim 8, wherein the spacer particles comprise greater than 50 mass % of one of In, Ga, Bi, or Sn.

11. A method of sintering, comprising:
dispensing a sintering paste mixture on a substrate, wherein the sintering paste mixture includes a plurality of spacer particles, a plurality of silver particles, and solvent, wherein the plurality of spacer particles have an average particle diameter within a target bond line thickness range of a joint formed by sintering an assembly using the sintering paste mixture;
placing a device on the sintering paste mixture to form an assembly; and
sintering the assembly to form a sintered joint, wherein the sintered joint has a bond line thickness within the target bond line thickness range.

12. The method of claim 11, wherein the plurality of spacer particles are less than 4 wt % of the sintering paste mixture.

13. The method of claim 12, wherein the target bond line thickness range is between 30 μm and 300 μm.

14. The method of claim 13, further comprising: forming the sintering paste mixture, wherein the sintering paste mixture is formed by mixing the plurality of spacer particles with a sintering paste comprising the plurality of silver particles and the solvent.

15. The method of claim 13, wherein the assembly is sintered at a pressure between 5 and 35 psi.

16. The method of claim 13, wherein the amount of pressure applied during sintering is based at least in part on the wt % of the plurality of spacer particles.

17. The method of claim 13, wherein the device is a die comprising a circuit board.

18. A sintered joint formed by a process, the process comprising:
dispensing a sintering paste mixture on a substrate, wherein the sintering paste mixture includes a plurality of spacer particles, a plurality of silver particles, and solvent, wherein the plurality of spacer particles have an average particle diameter within a target bond line thickness range of a joint formed by sintering an assembly using the sintering paste mixture;
placing a device on the sintering paste to form an assembly; and
sintering the assembly to form the sintered joint, wherein the sintered joint has a bond line thickness within the target bond line thickness range.

19. The sintering joint of claim 18, wherein the plurality of spacer particles are less than 4 wt % of the sintering paste mixture, and wherein the target bond line thickness range is between 30 μm and 300 μm.

20. The sintering joint of claim 19, wherein the assembly is sintered at a pressure between 5 and 35 psi, and wherein the amount of pressure applied during sintering is based at least in part on the wt % of the plurality of spacer particles.

21. The sintered joint of claim 18, the process further comprising: forming the sintering paste mixture by: mixing a plurality of spacer particles, a plurality of silver particles, and solvent.
